(19) United States
(12) Patent Application Publication
(10) Pub. No.: US 2002/0127852 A1
(43) Pub. Date: Sep. 12, 2002

(54) Method of manufacturing semiconductor integrated circuit device and semiconductor manufacturing apparatus

(76) Inventors: Kazuya Kawakami, Machida (JP); Yukihiro Suzuki, Ome (JP); Ken Okutani, Tachikawa (JP); Susumu Kajita, Kawasaki (JP); Takeshi Hashimoto, Tokyo (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/084,943

(22) Filed: Mar. 1, 2002

(30) Foreign Application Priority Data
Mar. 2, 2001 (JP) 2001-57974

(51) Int. Cl. H01L 21/44; H01L 21/302; H01L 21/461; C23C 16/00

(52) U.S. Cl. 438/680; 438/660; 438/689; 118/715; 118/722

(57) ABSTRACT

Disclosed is a technique capable of suppressing the damage of a semiconductor manufacturing apparatus due to the breakage or the crack to the minimum by surely detecting the breakage or the crack on a part of a wafer in a semiconductor manufacturing apparatus of a multi-chamber system. An entire image of a wafer is photographed by a camera in each time when the wafer is processed, and the photographed image is processed by a discrimination unit, thereby determining the presence of the breakage or the crack on the wafer. When the breakage or the crack is detected, an error signal is transmitted from the discrimination unit to a computer that controls the semiconductor manufacturing apparatus, and the operations of the process chamber and the transport chamber used immediately before the detection of the breakage or the crack on the wafer are stopped.

### TECHNICAL FIELD OF THE INVENTION

The present invention relates to a method of manufacturing a semiconductor integrated circuit device and to a semiconductor manufacturing apparatus, more particularly, to a technique effectively applicable to a method of manufacturing a semiconductor integrated circuit device, using a semiconductor manufacturing apparatus having a plurality of chambers.

### BACKGROUND OF THE INVENTION

Recently, with higher integration and scaling down of a semiconductor device, the method of manufacturing a semiconductor integrated circuit device using a batch-type semiconductor manufacturing apparatus in which a great number of semiconductor wafers (hereinafter, referred to as wafer) are processed simultaneously has had difficulty adapting to such strict process conditions. Since the batch-type semiconductor manufacturing apparatus has a limitation in its ability to secure the accuracy and uniformity in processing a semiconductor device, a breakthrough in technology has been demanded.

As means to meet the demand described above, a semiconductor manufacturing apparatus employing a system of using a plurality of single wafer processing chambers (hereinafter, referred to as multi-chamber system) is favorably used. The multi-chamber semiconductor manufacturing apparatus is provided with, for example, a transport chamber being at the center thereof in which a robot arm for transporting a wafer is installed, and a plurality of chambers and load-lock chambers.

It is only one wafer that the single wafer chamber can process in one operation. However, the use of the single wafer chamber makes it possible to achieve more accurate processing and to keep the uniformity in comparison to the batch-type chamber. Therefore, the single wafer chamber is superior in adaptation to the strict condition. In addition, since the process using the single wafer chamber can be carried out in a small chamber, if a plurality of chambers are provided in one semiconductor manufacturing apparatus, the single wafer chamber can show the ability not less than the batch-type chamber in terms of throughput.

In the multi-chamber semiconductor manufacturing apparatus, if transportation operation is carried out in a state where no wafer is placed on a robot arm due to an accident, processes proceed under such a condition in which no wafer is transported in the chamber, resulting that the chamber is damaged. In order to prevent this, an optical sensor is provided at each gate of the chambers and confirms the presence of the wafer on the robot arm.

For example, in Japanese Patent Application Laid-Open Publication number 61-263135, there is disclosed a technique in which a laser beam is applied to the peripheral portion of a wafer, the reflected light of the laser beam is detected by a reflected light detector, and the presence of the breakage and the crack in the peripheral portion of the wafer is detected on the basis of a detection output of the reflected light detector.

Also, in Japanese Patent Application Laid-Open Publication number 7-58175, there is disclosed a wafer inspecting equipment in which, even in case of a broken wafer, a shape of the wafer is photographed, the center of gravity of the wafer is detected by the image processing of the picture signal showing the shape of the wafer, the broken wafer is carried so as not to drop down in its way, and then, inspection of the electric element circuit formed on an element-forming surface of the wafer is performed.

Also, in Japanese Patent Application Laid-Open Publication number 60-85511, there is disclosed a method in which, in a semiconductor manufacturing apparatus using a batch-type chamber, the breakage of a wafer is detected by a micro switch or an optical sensor capable of detecting the breakage when contacting to the broken wafer based on the fact that a broken wafer is slanted on a wafer stage due to the shift of the center of gravity, and then the operation of the semiconductor manufacturing apparatus is stopped.

Also, in Japanese Patent Application Laid-Open Publication number 6-308042, there is disclosed a method in which scattered light having a predetermined wavelength is irradiated to a wafer, the light reflected from the wafer is photographed by a camera, the photographed image is displayed on a monitor, and whereby the crack of a wafer is observed and detected.

Also, in Japanese Patent Application Laid-Open Publication number 64-9303, there is disclosed a technique in which a wafer is photographed by a camera, the photographed image is digitalized, and thereafter, the digitalized image is processed by using a Fourier transform, thereby determining the center (center of gravity) of the wafer.

### SUMMARY OF THE INVENTION

The inventors of this invention found out that the method of confirming the presence of the wafer on the robot arm by providing an optical sensor at each gate of the chambers had problems as follows.

That is, during the processes performed to a wafer in each chamber such as the film formation by the CVD (Chemical Vapor Deposition) method, the film formation by the PVD (Physical Vapor Deposition) method, and the dry etching, damages such as breakage and crack often occur in a part of the wafer due to thermal stress applied thereto during the process or an accident during the transportation thereof. If a stress is applied to a wafer having the crack, the wafer may be broken from the crack. Since the above-described optical sensor is provided with an aim to determine the presence of the wafer on the robot arm, the optical sensor observes only a predetermined part of the wafer in general. Therefore, such an optical sensor can not detect the breakage or the crack in a part of the wafer completely.

When transporting the wafer with the breakage and the crack to the next chamber and performing, for example, a deposition step of a metal film by the PVD method, the metal film is deposited on an electrostatic chuck to fix the wafer, and as a result, the electrostatic chuck and other shield parts in the chamber have to be replaced disadvantageously. Therefore, maintenance including cleaning is needed to all of the chambers through which the wafer with the breakage and the crack passes. Consequently, it disadvantageously takes much time to restart to manufacture the semiconductor integrated circuit device. In addition, since the parts replacement and the cleaning are required, the manufacturing cost of the semiconductor integrated circuit device is problematically increased.

Also, if fragments of the broken wafer are scattered to other wafers stored in the load-lock chamber, the stored wafers are also damaged and become defective. Recently, transition to larger diameter wafers has been accelerated, but the larger diameter causes the increase of cost per wafer. If the number of defective wafers produced is increased, the manufacturing cost of the semiconductor integrated circuit device is further increased. Therefore, it is further necessary to take measures to the problem described above.

An object of the present invention is to provide a technique capable of detecting defects such as a breakage and a crack on a wafer in the step of wafer processing using a semiconductor manufacturing apparatus employing the multi-chamber system.

The above and other objects and novel features of the present invention will be readily apparent from the description and the accompanying drawings of this specification.

The advantages achieved by the typical ones of the inventions disclosed in this application will be briefly described as follows.

Specifically, an aspect of the present invention is a method of manufacturing a semiconductor integrated circuit device performed in a semiconductor manufacturing apparatus having a plurality of chambers, comprising the steps of: obtaining a flat entire image of a semiconductor wafer after performing a first process to the semiconductor wafer in a first chamber of the plurality of chambers and before performing a second process to the semiconductor wafer in a second chamber of the plurality of chambers; determining the condition of the semiconductor wafer by examining the flat entire image of the semiconductor wafer; transporting the semiconductor wafer to the second chamber and performing the second process to the semiconductor wafer when determined that the semiconductor wafer is in proper condition; and stopping the operation of the semiconductor manufacturing apparatus when determined that the semiconductor wafer is in improper condition.

Also, another aspect of the present invention is a method of manufacturing a semiconductor integrated circuit device using a semiconductor manufacturing apparatus having a plurality of chambers, comprising the steps of: transporting a semiconductor wafer to a first chamber of the plurality of chambers, and then performing a first process to the semiconductor wafer; photographing a flat entire image of the semiconductor wafer by a photographing unit after taking out the semiconductor wafer from the first chamber, and setting the photographed flat entire image as a first image; taking the first image in a discrimination unit and determining the presence of the damages on the semiconductor wafer; stopping the operation of the semiconductor manufacturing apparatus when determined that the semiconductor wafer is damaged; and transporting the semiconductor wafer to the second chamber and performing a second process to the semiconductor wafer when determined that the semiconductor wafer is not damaged.

Also, another aspect of the present invention is a semiconductor manufacturing apparatus, wherein

(a) a plurality of chambers and a transport chamber are mechanically connected to each other;

(b) a photographing unit for obtaining a flat entire image of a semiconductor wafer, to which a predetermined process has been performed in a predetermined chamber of the plurality of chambers, is provided in the transport chamber;

(c) the semiconductor manufacturing apparatus has a function to determine the condition of the semiconductor wafer by examining the flat entire image of the semiconductor wafer; and

(d) the semiconductor manufacturing apparatus has a function to stop the operation of itself when determined that the semiconductor wafer is in improper condition.

Also, another aspect of the present invention is a semiconductor manufacturing apparatus, wherein

(a) a plurality of chambers and a transport chamber are mechanically connected to each other;

(b) a photographing unit for obtaining a flat entire image of a semiconductor wafer, to which a predetermined process has been performed in a predetermined chamber of the plurality of chambers, is provided in the transport chamber;

(c) the semiconductor manufacturing apparatus has a discrimination unit for determining the presence of damages on the semiconductor wafer by comparing the flat entire image of the semiconductor wafer with a flat entire image of a good semiconductor wafer recorded in advance; and

(d) the semiconductor manufacturing apparatus has a function to stop the operation of itself when the discrimination unit determines that the semiconductor wafer is damaged.

### BRIEF DESCRIPTION OF THE DRAWINGS

FIG. 1 is an explanatory diagram of a semiconductor manufacturing apparatus according to the first embodiment of the present invention;

FIG. 2 is an explanatory diagram of a load-lock chamber provided in the semiconductor manufacturing apparatus shown in FIG. 1;

FIG. 3 is an explanatory diagram of a transport chamber provided in the semiconductor manufacturing apparatus shown in FIG. 1;

FIG. 4 is a flow chart showing the steps of processing a photographed entire image of a wafer and the steps of controlling the semiconductor manufacturing apparatus after the process of the entire image of the wafer;

FIG. 5 is a flow chart showing a maintenance method of the transport chamber provided in the semiconductor manufacturing apparatus shown in FIG. 1;

FIG. 6 is a flow chart showing a maintenance method of the process chamber provided in the semiconductor manufacturing apparatus shown in FIG. 1;

FIG. 7A is an explanatory diagram showing a state where a broken wafer is placed on a robot arm in the transport chamber shown in FIG. 3, and FIG. 7B is an explanatory diagram showing a state where a broken wafer is place on slots in the load-lock chamber shown in FIG. 2;

FIG. 8 is a flow chart showing an example of a maintenance method of the load-lock chamber provided in the semiconductor manufacturing apparatus shown in FIG. 1;

FIG. 9 is an explanatory diagram of a constitution of a semiconductor manufacturing apparatus according to another embodiment of the present invention;

FIG. 10 is a plan view of a wafer showing a state where a thin film is formed on a wafer except an outer peripheral portion thereof;

FIG. 11 is a cross-sectional view showing an example of the principal part of a sputtering apparatus for forming the thin film shown in FIG. 10;

FIG. 12 is a plan view of a wafer on which a thin film formed on the wafer is displaced from a predetermined position;

FIG. 13A is a plan view of a wafer on which a predetermined thin film is formed, and FIG. 13B is a plan view of a wafer on which a predetermined thin film is not formed;

FIG. 14 is a cross-sectional view showing the principal part of a method of manufacturing a semiconductor integrated circuit device manufactured by using the semiconductor manufacturing apparatus shown in FIG. 1;

FIG. 15 is a cross-sectional view showing the principal part of the semiconductor integrated circuit device in a manufacturing step after that of FIG. 14;

FIG. 16 is a cross-sectional view showing the principal part of the semiconductor integrated circuit device in a manufacturing step after that of FIG. 15;

FIG. 17 is a cross-sectional view showing the principal part of the semiconductor integrated circuit device in a manufacturing step after that of FIG. 16;

FIG. 18 is a cross-sectional view showing the principal part of the semiconductor integrated circuit device in a manufacturing step after that of FIG. 17;

FIG. 19 is a cross-sectional view showing the principal part of the semiconductor integrated circuit device in a manufacturing step after that of FIG. 18;

FIG. 20 is a cross-sectional view showing the principal part of the semiconductor integrated circuit device in a manufacturing step after that of FIG. 19;

FIG. 21 is a cross-sectional view showing the principal part of the semiconductor integrated circuit device in a manufacturing step after that of FIG. 20;

FIG. 22 is a cross-sectional view showing the principal part of the semiconductor integrated circuit device in a manufacturing step after that of FIG. 21;

FIG. 23 is a cross-sectional view showing the principal part of the semiconductor integrated circuit device in a manufacturing step after that of FIG. 22;

FIG. 24 is a cross-sectional view showing the principal part of the semiconductor integrated circuit device in a manufacturing step after that of FIG. 23;

FIG. 25 is a cross-sectional view showing the principal part of the semiconductor integrated circuit device in a manufacturing step after that of FIG. 24;

FIG. 26 is a cross-sectional view showing another example of the principal part of a method of manufacturing a semiconductor integrated circuit device manufactured by using the semiconductor manufacturing apparatus shown in FIG. 1;

FIG. 27 is a cross-sectional view showing the principal part of the semiconductor integrated circuit device in a manufacturing step after that of FIG. 26;

FIG. 28 is a cross-sectional view showing the principal part of the semiconductor integrated circuit device in a manufacturing step after that of FIG. 27;

FIG. 29 is a cross-sectional view showing the principal part of the semiconductor integrated circuit device in a manufacturing step after that of FIG. 28;

FIG. 30 is a cross-sectional view showing the principal part of the semiconductor integrated circuit device in a manufacturing step after that of FIG. 29; and

FIG. 31 is a cross-sectional view showing the principal part of the semiconductor integrated circuit device in a manufacturing step after that of FIG. 30.

### DESCRIPTION OF THE PREFERRED EMBODIMENTS

In advance of describing the embodiments of the present invention, terms used in the embodiments will be described as follows.

A wafer includes a single crystal silicon substrate (having an approximately flat, round shape in general), a sapphire substrate, a glass substrate, other insulating or semi-insulating substrate, a semiconductor substrate, and a substrate made by combination thereof, which are used in the manufacture of an integrated circuit. In addition, a semiconductor integrated circuit device in this application is not limited to the one made on the semiconductor or insulating substrate such as the silicon wafer and the sapphire substrate, and it includes the one made on other insulating substrate such as glass, for example, TFT (Thin Film Transistor) and STN (Super-Twisted-Nematic) liquid crystal unless otherwise stated.

A single wafer type or a single wafer processing indicates a method in which various processes are performed to each one wafer. Since it is possible to control the process condition for each wafer, the method is superior in process precision and reproducibility, and has an advantage in reducing the size of the device itself.

Damages mean defects in appearance such as breakage, fracture, crack, and the like of a wafer.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of an element (including number of pieces, values, amount, range, or the like), the number of the element is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. This condition is also applicable to the numerical value and the range described above.

Also, in the drawings used in the embodiments, a thin film formed on a wafer is hatched in some cases even in a plan view so as to make the drawings easy to see.

In the following, the embodiments of the present invention will be described based on the accompanying drawings. Note that the components having the same function are added by the same reference symbol in the entire drawings for describing the embodiments, and repetitive descriptions thereof will be omitted.

(First Embodiment)

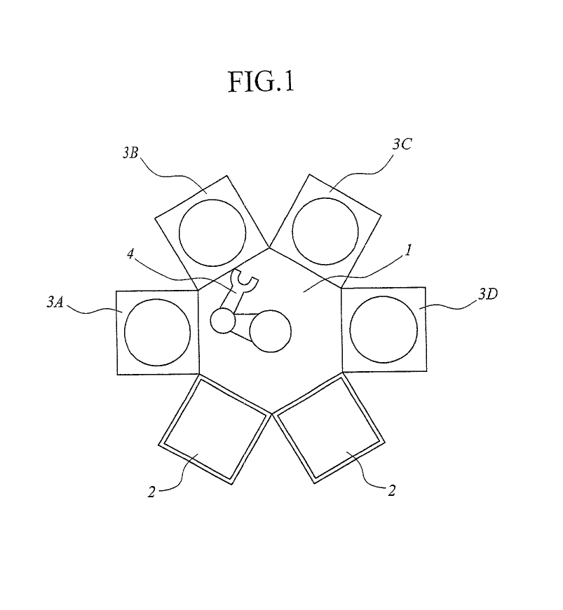

FIG. 1 shows a block diagram of a semiconductor manufacturing apparatus according to the first embodiment, in which a multi-chamber system is employed.

This semiconductor manufacturing apparatus is a single wafer processing type semiconductor manufacturing apparatus provided with a transport chamber 1, load-lock chambers 2, and process chambers 3A to 3D. A robot arm 4 is provided in the transport chamber 1, and the robot arm 4 can transport a wafer to the load-lock chambers 2 or to the process chambers 3A to 3D. In the process chambers 3A to 3D, various processes are performed to a wafer. The insides of the transport chamber 1, the load-lock chambers 2, and the process chambers 3A to 3D are kept in vacuum, and the transportation of a wafer can be performed without exposing the wafer to the outer atmosphere. In other words, in the semiconductor manufacturing apparatus in this first embodiment, various processes can be performed to a wafer without causing a reaction on a wafer surface. In FIG. 1, the case where four process chambers 3A to 3D are provided is exemplified. However, if there are more than four steps to be performed without exposing the wafer to the outer atmosphere of the semiconductor manufacturing apparatus, additional process chambers can be provided depending on the number of steps. In addition, if the number of steps is three or less, the number of process chambers can also be reduced depending on the number of steps.

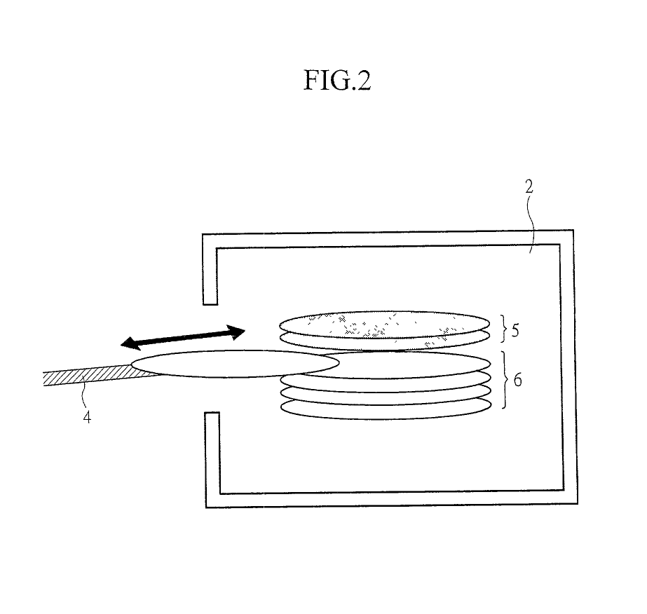

In the semiconductor manufacturing apparatus shown in FIG. 1, the wafer is processed in each of the process chambers in the order of process chambers 3A to 3D. Also, as shown in FIG. 2, the load-lock chamber 2 can store processed wafers 5, which have been processed in the process chambers 3A to 3D, and unprocessed wafers 6, which have not been processed yet.

The unprocessed wafer 6 stored in the load-lock chamber 2 is taken out from the load-lock chamber 2 by the robot arm 4, and transported to the process chamber 3A (process chamber, first process chamber). After a heat treatment (first process) for degassing the wafer and processes (first process) for an element forming surface (first surface) such as etching and forming a thin film are performed to the unprocessed wafer 6 transported to the process chamber 3A, the wafer 6 is taken out from the process chamber 3A by the robot arm 4.

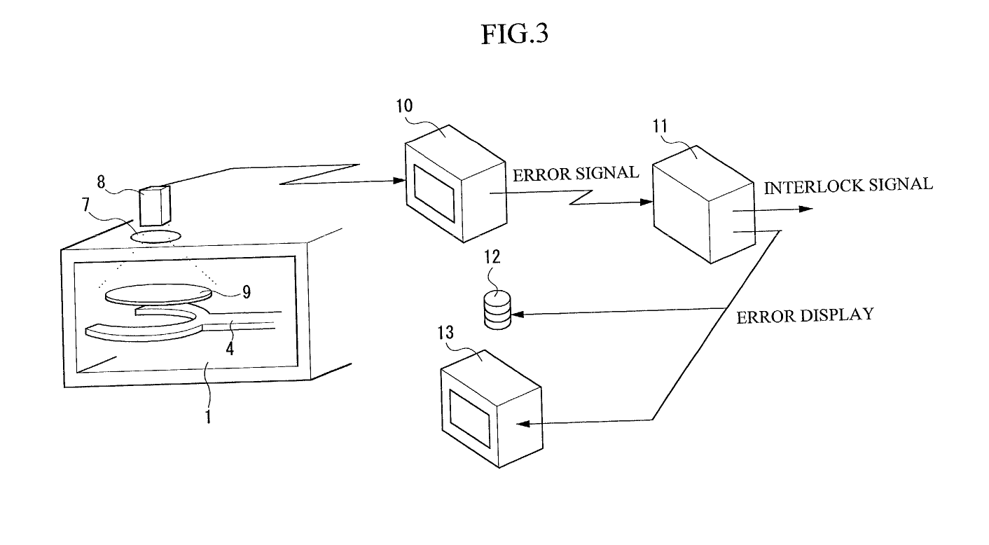

Incidentally, in the process chamber 3A, damages such as breakage and crack may occur in a part of the wafer due to thermal stress applied thereto during the process or an accident during the transportation thereof. Therefore, in the first embodiment, a photographing unit for obtaining a two-dimensional image data of the entire wafer is provided near a gate of each process chamber in the transport chamber 1. FIG. 3 is an explanatory diagram thereof. Here, the structure of FIG. 3 will be described.

In the transport chamber 1, a wide-angle lens 7 (photographing unit) such as a fish-eye lens is provided near the gate to the process chamber 3A, which makes it possible to photograph the entire image of a wafer 9 right after being processed in the process chamber 3A on the robot arm 4 from the top of the transport chamber 1 by the use of a camera 8 (photographing unit) such as a CCD (charge coupled device) camera. This entire image of the wafer 9 is a two-dimensional image. In this case, when the radius of the wafer 9 to be photographed is 200 mm, the entire image of the wafer 9 can be photographed at a time by using a camera 8 with the 2500000 pixels.

For the same reason as described above, wide-angle lenses 7 are provided near the gate to each of the process chambers 3B to 3D, which makes it possible to photograph the entire image of wafers 9 right after being processed in the process chambers 3B to 3D on the robot arm 4 from the top of the transport chamber 1 by the use of the camera 8 such as a CCD camera.

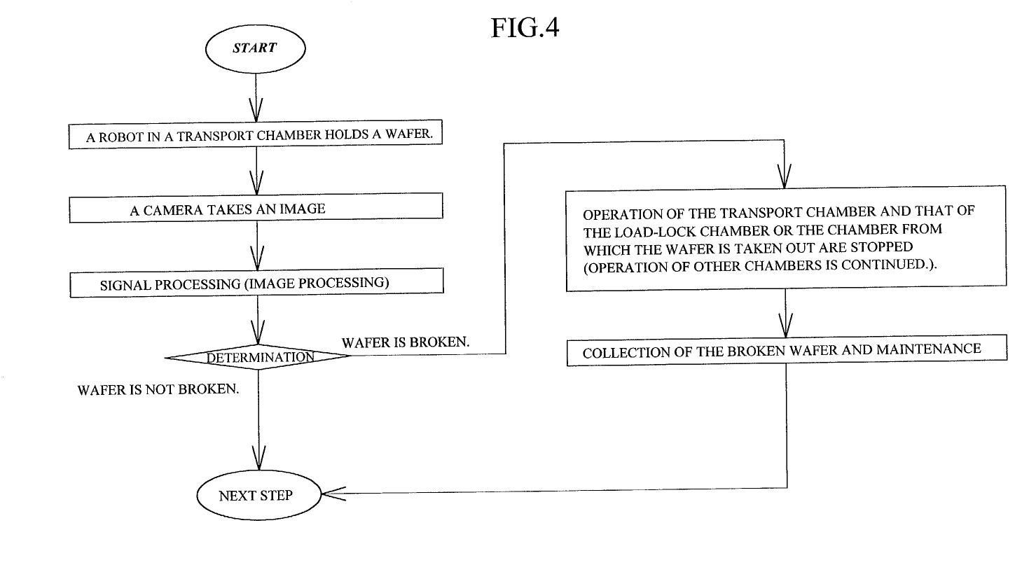

Next, description will be made for the step of processing the entire image of the wafer 9 photographed by the camera 8 and the step of controlling the semiconductor manufacturing apparatus after processing the entire image of the wafer 9 with reference to FIGS. 3 and 4. FIG. 4 is a flow chart showing the steps of processing the entire image of the wafer 9 photographed by the camera 8 and the steps of controlling the semiconductor manufacturing apparatus after processing the entire image of the wafer 9.

First, after the wafer 9 is taken out from the process chamber 3A to the transport: chamber 1 by the robot arm 4, the wafer 9 is held at a position capable of photographing the entire image of the wafer 9 by the camera 8 via the wide-angle lens 7.

Next, the entire image of the wafer 9 is photographed by the camera 8 via the wide-angle lens 7. The photographed entire image (first image) of the wafer 9 is transmitted from the camera 8 to a discrimination unit 10. Thereafter, signal processing (image processing) is performed thereto by the discrimination unit 10. This signal processing converts the entire image of the wafer 9 into, for example, gray scale image data having 256 stages (multi gradation). Also, the photographed entire image of the wafer 9 can be displayed on a monitor display of the discrimination unit 10.

The entire image of the wafer 9 subjected to the signal processing is compared with the image data of the wafer 9 having no breakage and crack recorded in advance in the discrimination unit 10. When there is the breakage or the crack on the wafer 9, the color tone in the gray scale of the portion where the breakage or the crack occurs is different from that of the other portion in the gray-scale image data. Therefore, it becomes possible to detect the presence of the breakage or the crack. When it is confirmed as a result of the comparison that there is no breakage or the crack on the wafer 9 photographed by the camera 8, the wafer 9 is transported to the process chamber 3B (process chamber, second process chamber), and the next process (second process) is performed thereto. To the contrary, when the presence of the breakage or the crack is detected, the discrimination unit 10 transmits an error signal to a computer 11 which controls the semiconductor manufacturing apparatus according to the first embodiment.

The computer 11 received with the error signal transmits an interlock signal to the semiconductor manufacturing apparatus according to the first embodiment to stop the operation in the transport chamber 1 and the process chamber 3A. At this time, if the process chambers 3B to 3D are in operation, the process chambers 3B to 3D stop their operations at the time when the processes to the wafers in the process chamber 3B to 3D are finished, and the wafers subjected to the process are stayed in the process chambers 3B to 3D. The computer 11 transmits the interlock signal to the semiconductor manufacturing apparatus according to the first embodiment and turns on, for example, a pilot lamp 12 to display the error content on a computer 13 for an operator, thereby notifying the operator of the semiconductor manufacturing apparatus according to the first embodiment that the operations in the transport chamber 1 and the process chamber 3A are stopped.

When defects are detected on the wafer 9 as described above, the wafer 9 on which the breakage or the crack is detected is collected, and subsequently, the maintenance of the transport chamber 1 and the process chamber 3A is performed.

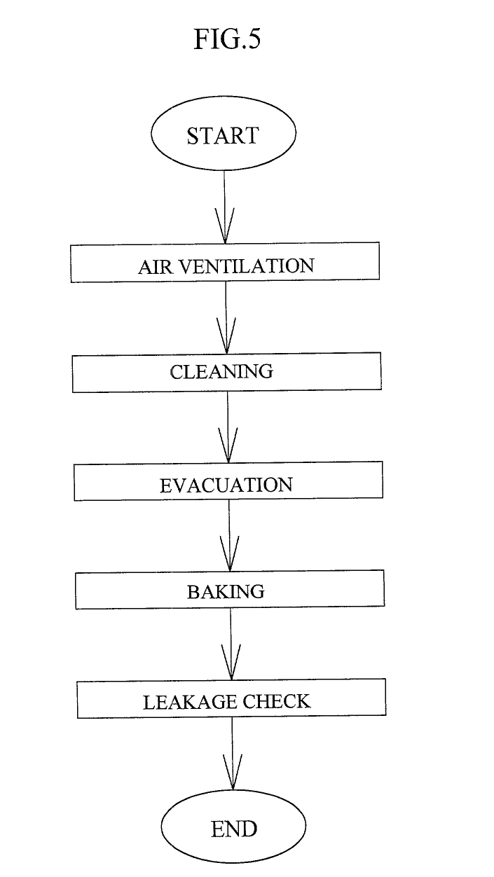

In the maintenance of the transport chamber 1 as shown in FIG. 5, the transport chamber 1 is ventilated, and subsequently, the chamber is cleaned to remove the fragments and the dusts of the wafer 9 scattered in the transport chamber 1. This cleaning is performed in order to prevent the fragments and the dusts of the broken wafer 9 from adhering to the wafer 9 passing through the transport chamber 1 when the maintenance of the transport chamber 1 is finished and the operation of the semiconductor manufacturing apparatus according to the first embodiment is restarted.

Next, after the evacuation of the transport chamber 1, the transport chamber 1 is heated by the baking to remove the moisture adhered to the inner wall of the transport chamber 1. Thereafter, the leak check is carried out to check the vacuum leakage in the transport chamber 1. If it is confirmed that there is no vacuum leakage, the maintenance of the transport chamber 1 is completed.

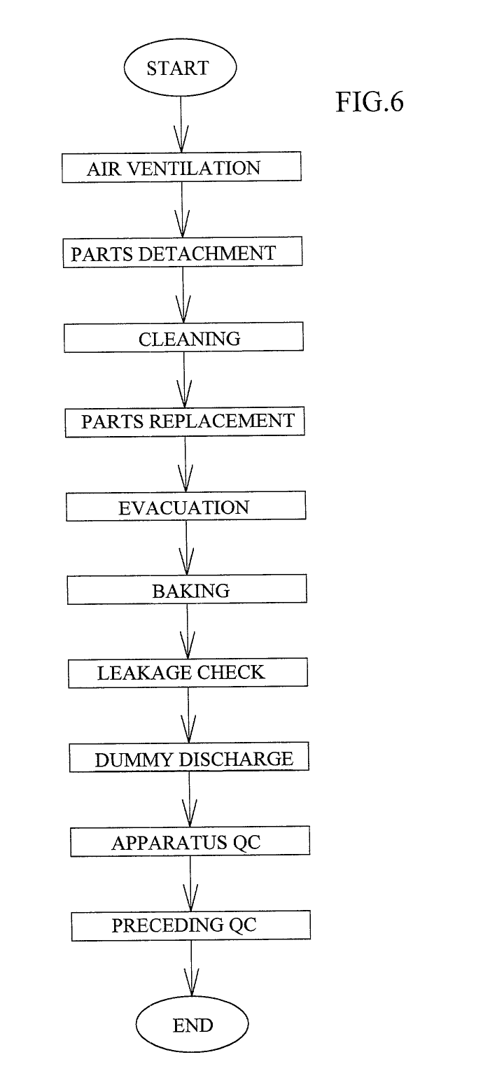

As an example of the maintenance of the process chamber 3A, the maintenance in the case where the process chamber 3A is a sputtering (physical deposition method) apparatus which performs the process in vacuum will be described by the use of FIG. 6.

First, the process chamber 3A is ventilated. Subsequently, of the parts of the process chamber 3A (sputtering apparatus) such as an electrostatic chuck and a shield, the ones to which a thin film has been adhered due to the sputtering are removed. This removal is performed in order to prevent the thin film formed on the parts of the process chamber 3A from adhering to the wafer 9 transported to the process chamber 3A when the maintenance of the process chamber 3A is finished and the operation of the semiconductor manufacturing apparatus according to the first embodiment is restarted.

Next, the process chamber 3A is cleaned to remove the fragments and the dusts of the wafer 9 scattered in the process chamber 3A. Similarly to the step P6B (refer to FIG. 5) in the maintenance of the transport chamber 1, this cleaning is performed in order to prevent the fragments and the dusts of the wafer 9 from adhering to the wafer 9 transported to the process chamber 3A when the maintenance of the process chamber 3A is finished and the operation of the semiconductor manufacturing apparatus according to the first embodiment is restarted.

Next, the parts are replaced, that is, new parts of the same kinds as the removed parts are installed to the process chamber 3A. Next, after the evacuation of the process chamber 3A, the process chamber 3A is heated by means of the baking to remove the moisture adhered to the inner wall of the process chamber 3A. Thereafter, the leak check is carried out to check the vacuum leakage in the process chamber 3A. If it is confirmed that there is no vacuum leakage, the maintenance of the process chamber 3A proceeds to the next step.

Next, a dummy discharge is performed to about 25 to 70 wafers in the process chamber 3A. This dummy discharge is performed in order to secure the stability in the deposition steps of the wafer in the process chamber 3A when the maintenance of the transport chamber 1 and the process chamber 3A is finished and the operation of the semiconductor manufacturing apparatus according to the first embodiment is restarted.

Next, the process chamber 3A is experimentally operated by an apparatus QC (Quality Control) to check the quality of the thin film formed by the process chamber 3A, thereby confirming whether the process chamber 3A is operated properly or not. The quality mentioned here includes the sheet resistance, the reflectance, the film thickness of the thin film, the presence of the foreign particles contained in the thin film, and the like in the case where, for example, the thin film is made of aluminum (Al).

Subsequently, the process chamber 3A is operated by the preceding QC in the same condition as that of the deposition step of the wafer for a product, and the quality of the formed thin film is checked. The quality mentioned here includes the sheet resistance, the reflectance, the film thickness of the thin film, the presence of the foreign particles contained in the thin film, and the like in the case where, for example, the thin film is made of Al. If there is no defects found in the process chamber 3A in this step P6O, the maintenance of the process chamber 3A is completed. If the maintenance of the transport chamber 1 is also finished, the operation of the semiconductor manufacturing apparatus according to the first embodiment can be restarted.

In a method in which the photographing unit of the first embodiment is not provided but an optical sensor is provided at the gate of the process chamber 3A to confirm the presence of the wafer 9 on the robot arm, since only a predetermined portion of the wafer 9 is observed in general, the presence of the breakage or the crack on the part of the wafer 9 can not be detected in some cases. Therefore, the operation of the semiconductor manufacturing apparatus is not stopped, resulting that the wafer 9 is transported to the process chamber 3B of the next step and the predetermined process is performed to the wafer 9. In the case where, for example, the process chamber 3B is the sputtering apparatus, the thin film is also formed on the parts of the process chamber 3B such as the electrostatic chuck and the shield. Particularly, if the thin film is formed on the heater of the electrostatic chuck type or the heater is damaged, it becomes impossible to keep the temperature uniform, resulting in the replacement of the parts. Moreover, if the presence of the breakage or the crack on the wafer 9 is not detected even after the process in the process chamber 3B, the wafer 9 is transported to the process chamber 3C and the next process is performed thereto. More specifically, the damage of the process chamber 3A reaches each of the plurality of process chambers, and the maintenance similar to those of the transport chamber 1 and the process chamber 3A must be done to the process chambers which have performed the process to the wafer 9 on which the breakage or the crack occurs. That is, the troublesome maintenance is required to each of the process chambers, and as a result, it takes much time (at least about 24 hours) to restart the operation of the semiconductor manufacturing apparatus, which causes the delay in the delivery date and the increase of the manufacturing cost. Although the multi-chamber is employed in order to perform the process in a short time and with a high yield, the above problem becomes severer with the increase of the number of chambers.

Contrary to this, in the semiconductor manufacturing apparatus according to the first embodiment, the entire image of the wafer 9 on the robot arm 4 is photographed at each position of the process chambers 3A to 3D immediately after performing the process to the wafer 9 to determine the presence of the breakage or the crack on the wafer 9. Therefore, it is possible to prevent the wafer 9 having the breakage or the crack thereon from being transported to the process chamber performing the next step or the load-lock chamber 2 without fail. More specifically, when the breakage or the crack on the wafer 9 is detected, the maintenance is needed to perform only to the process chamber and the transport chamber used in the step immediately before the breakage or the crack is detected on the wafer 9. As a result, since the maintenance to other process chambers can be omitted, the amount of time required to perform the maintenance of the process chamber can be reduced. Also, since the maintenance to other process chambers can be omitted, the parts replacement is not required in other process chambers and the amount of time required to replace the parts can be reduced. In addition, since the parts replacement is not required in other process chambers, the manufacturing cost of the semiconductor integrated circuit device manufactured by using the semiconductor manufacturing apparatus according to the first embodiment can be reduced.

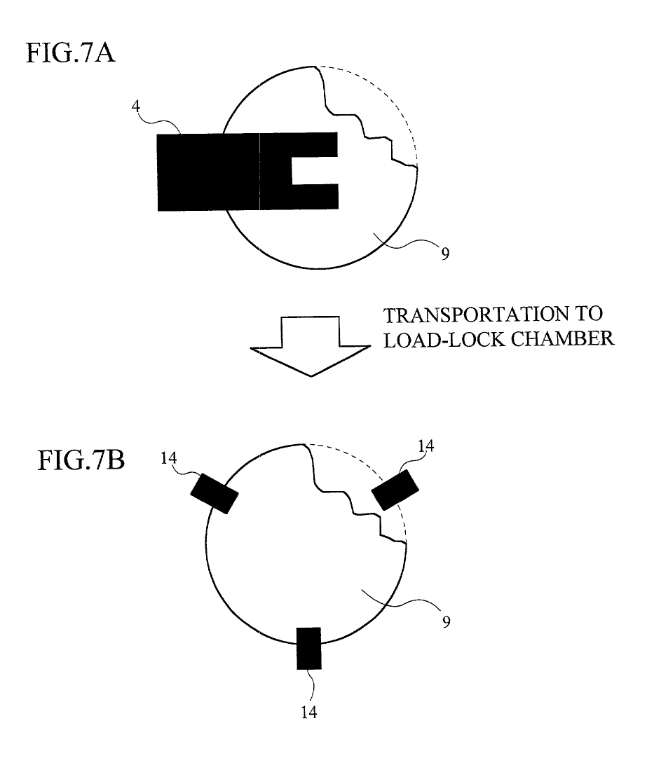

The wafer 9 subjected to the processes in the process chambers 3A to 3D is stored again in the load-lock chamber 2. At this time, as shown in FIG. 7A, the robot arm 4 transporting the wafer 9 to the load-lock chamber 2 can hold the wafer 9 even if the wafer 9 is broken in some cases. As shown in FIG. 7B, however, the wafer 9 is held by slots 14 in the load-lock chamber 2, and therefore, the slots 14 can not hold the broken wafer 9 in some cases. The wafer 9, which the slots 14 can not hold, drops from the slots 14 and does damage to other wafers stored in the load-lock chamber 2. Also, since the fragment and the dusts of the wafer 9 dropped from the slots 14 are scattered to other wafers in the load-lock chamber 2, other wafers may also become defective. In the above optical detection technique, the above-described problems may occur.

Contrary to this, in the semiconductor manufacturing apparatus according to the first embodiment, the entire image of the wafer 9 on the robot arm 4 is photographed in the process chamber 3D immediately after performing the process to the wafer 9 to determine the presence of the breakage or the crack on the wafer 9. And then, if the breakage or the crack of the wafer 9 is detected, the operation of the semiconductor manufacturing apparatus is stopped, and if the breakage or the crack of the wafer 9 is not detected, the wafer is transported to the load-lock chamber 2. Thus, it is possible to prevent the wafer 9 having the breakage or the crack thereon from being transported to the load-lock chamber 2 without fail. Therefore, it is possible to prevent the wafer 9 from dropping from the slots 14 without fail. More specifically, the parts replacement and the maintenance in the load-lock chamber 2 can be omitted. Also, since it is possible to prevent the case where a defective wafer makes other wafer stored in the load-lock chamber 2 defective, the improvement of the yield and the reduction of the manufacturing cost of the semiconductor integrated circuit device can be achieved.

Also, it is also possible to provide the photographing unit (refer to FIG. 3) near the gate of the transport chamber 1 to the load-lock chamber 2 in consideration of the occurrence of the breakage and the crack in a part of the wafer due to the accident during the transportation of the wafer. In this case, the entire image (third image) of the unprocessed wafer 6 (refer to FIG. 2) taken out from the load-lock chamber 2 by the robot arm 4 can be observed by the use of the camera 8 (refer to FIG. 3) from the top of the transport chamber 1. This observation makes it possible to detect the breakage and the crack even in the case where the breakage and the crack occur in a part of the unprocessed wafer 6 due to the accident when taking out the unprocessed wafer 6 from the load-lock chamber 2.

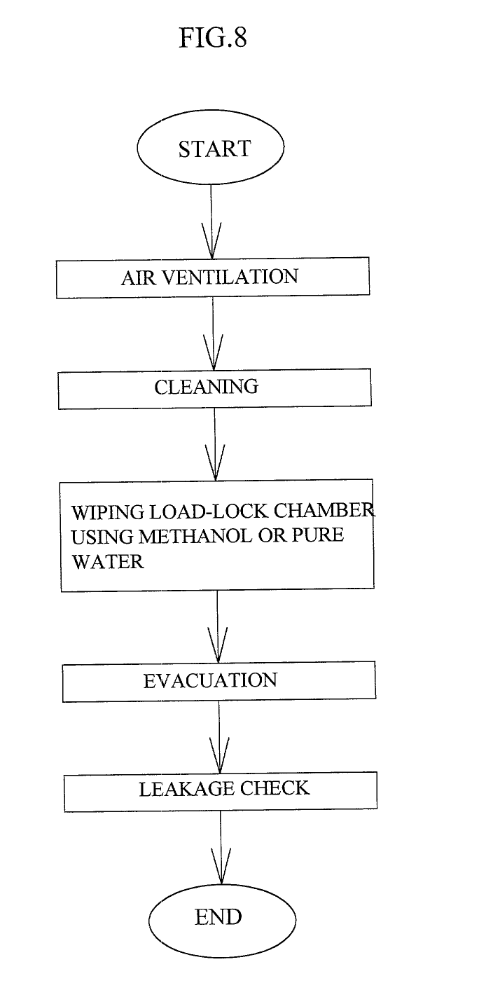

FIG. 8 is a flow chart showing an example of the maintenance step of the load-lock chamber 2 in the case where the breakage and the crack on the unprocessed wafer 6 is detected. When the breakage and the crack on the unprocessed wafer 6 are detected, the load-lock chamber 2 is first ventilated. Subsequently, the load-lock chamber 2 is cleaned to remove the fragments and the dusts of the unprocessed wafer 6 scattered in the load-lock chamber 2. This cleaning is performed in order to prevent the fragments and the dusts of the broken unprocessed wafer 6 from adhering to the processed wafer 5 (refer to FIG. 2) stored in the load-lock chamber 2 when the maintenance of the load-lock chamber 2 is finished and the operation of the semiconductor manufacturing apparatus according to the first embodiment is restarted.

Next, after wiping the inside of the load-lock chamber 2 using an alphawipe holding methanol or the pure water, the load-lock chamber 2 is evacuated. Thereafter, the vacuum leakage in the load-lock chamber 2 is checked, and if it is confirmed that there is no vacuum leakage, the maintenance of the load-lock chamber 2 is completed.

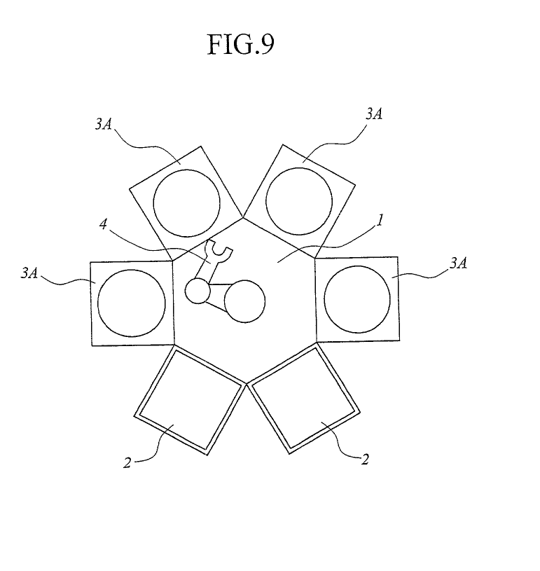

Incidentally, the same process chambers, for example, the process chamber 3A may be used as all of the process chambers provided in the semiconductor manufacturing apparatus (refer to FIG. 1) according to the first embodiment as shown in FIG. 9, and after transporting the unprocessed wafer 6 (refer to FIG. 2) taken out from the load-lock chamber 2 by the robot arm 4 to each of the process chambers 3A one by one, the process of the same steps may be performed to the unprocessed wafer 6. Thereby, the throughput of the semiconductor manufacturing apparatus according to the first embodiment can be improved. Note that the same kind of process chamber may be used as the two or more process chambers, not all of the process chambers, provided in the semiconductor manufacturing apparatus.

FIG. 10 shows a case where a thin film 15 (first thin film) is not formed on a peripheral portion of the wafer 9 by using a mask when forming the thin film 15 on the wafer 9. Although FIG. 10 is a plan view, the thin film 15 is hatched so as to make FIG. 10 easy to see.

If the thin film 15 is formed also on the peripheral portion of the wafer 9, the; unnecessary thin film 15 formed on the peripheral portion is difficult to be removed. Therefore, in the case where the thin film 15 is a metal film made of, for example, copper, the unremoved thin film 15 is diffused by the heat treatment or the like, which causes the decrease of the yield of the semiconductor integrated circuit device. Consequently, development of a method of avoiding the formation of the thin film 15 on the peripheral portion of the wafer 9 is needed.

The thin film 15 can be formed by using, for example, a sputtering apparatus shown in FIG. 11. The sputtering apparatus is provided with a target 16, shields 17A and 17B, and a heater 18, and the wafer 9 is placed on the heater 18. Sputter particles 19 sputtered from the target 16 are deposited on the wafer 9 to form the thin film 15. At this time, the edge portion 17C of the shield 17B serves as a mask and the thin film 15 is formed on the wafer 9 except the outer peripheral portion thereof.

However, when the position of the mask is accidentally displaced from that of the wafer 9, the area in which the thin film 15 is formed on the wafer 9 is displaced from the predetermined position as shown in FIG. 12. Note that though FIG. 12 is a plan view, the thin film 15 is hatched so as to make FIG. 12 easy to see.

As described above, in the semiconductor manufacturing apparatus according to the first embodiment, the breakage and the crack in a part of the wafer 9 are detected by processing the entire image of the wafer 9 photographed by the camera 8 (refer to FIG. 3), and therefore, it is also possible to detect that the area in which the thin film 15 is formed is displaced from the predetermined position. More specifically, by performing the steps similar to those described by the use of FIG. 4, it is possible to detect that the area in which the thin film 15 is formed is displaced from the predetermined position and also possible to stop the operation of the process chamber and the transport chamber 1 in which the thin film 15 is formed. In this; case, in the step P4 (refer to FIG. 4), the image data of the entire image of the wafer 9 on which the thin film 15 is formed at a predetermined position recorded in advance in the discrimination unit 10 is compared with the image data of the entire image of the wafer 9 photographed at that time.

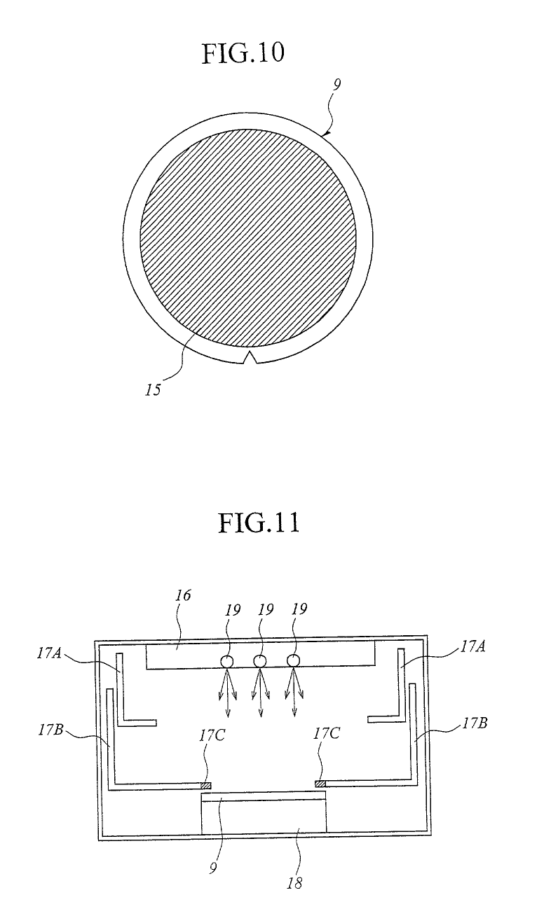

FIG. 13A is a plan view showing the wafer 9 in a state where the predetermined thin film 15 is formed on the wafer 9, and FIG. 13B is a plan view showing the wafer 9 in a state where the predetermined thin film 15 is not formed on the wafer 9 due to an accident. In the semiconductor manufacturing apparatus according to the first embodiment, even if the accident that the predetermined thin film 15 is not formed occurs in the process chamber as shown in FIG. 13B, by performing the steps similar to those described above by the use of FIG. 4, it is possible to detect that the thin film 15 is not formed. More specifically, in the semiconductor manufacturing apparatus according to the first embodiment, the film condition of the deposited thin film 15 can be confirmed immediately after the step of forming the thin film 15. In this case, in the step P4 (refer to FIG. 4), the image data of the entire image of the wafer 9 on which the thin film 15 is formed at a predetermined position recorded in advance in the discrimination unit 10 is compared with the image data of the entire image of the wafer 9 photographed at that time.

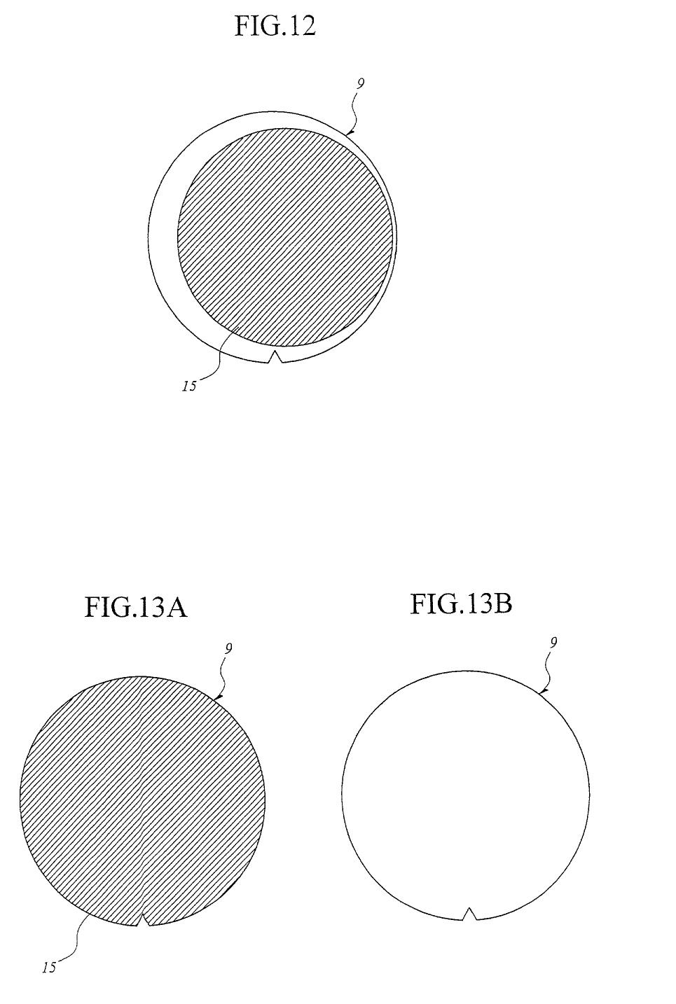

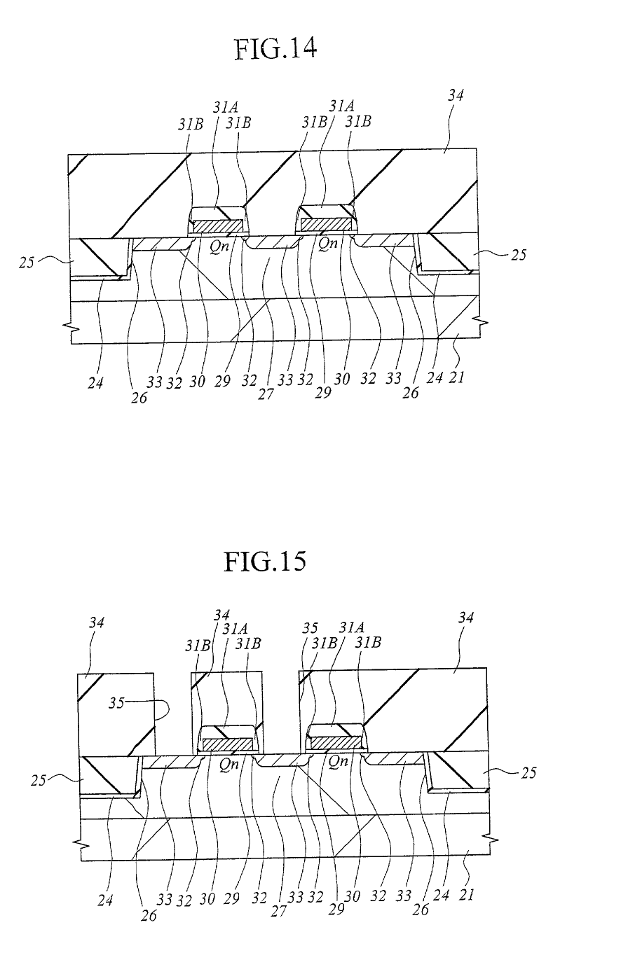

Next, the method of manufacturing a semiconductor integrated circuit device using the semiconductor manufacturing apparatus according to the first embodiment will be described by the use of FIGS. 14 to 25.

First, as shown in FIG. 14, a semiconductor substrate 21 (wafer 9) made of single crystal silicon having resistivity of about 10 Ωcm is subjected to a heat treatment at the temperature of about 850° C. to form a thin silicon oxide film (pad oxide film) having a film thickness of about 10 nm on a main surface (first surface) of the semiconductor substrate 21. Subsequently, after depositing a silicon nitride film having a film thickness of about 120 nm on the silicon oxide film by the CVD method, the dry etching using a photoresist film as a mask is performed to remove the silicon nitride film and the silicon oxide film in an. element isolation region. The silicon oxide film is formed with an aim to buffer the stress applied to the substrate, for example, when the silicon oxide film filled in the element isolation trench is densified (baked) in the latter steps. Also, since the silicon nitride film is hard to be oxidized, the silicon nitride film is used as a mask functioning to prevent the oxidation of the substrate surface below it (active region).

Subsequently, the dry etching using the silicon nitride film as a mask is performed. to form a trench having a depth of about 350 nm in the element isolation region in the semiconductor substrate 21. Thereafter, the semiconductor substrate 21 is subjected to a heat treatment at the temperature of about 1000° C. to form a thin silicon oxide film 24 having a film thickness of about 10 nm on the inner wall of the trench with an aim to remove the damage layer formed on the inner wall of the trench due to the etching.

Subsequently, a silicon oxide film 25 is deposited to a thickness of about 380 nm on the semiconductor substrate 21 by the CVD method, and then, the silicon oxide film 25 is densified (baked) by performing the heat treatment to the semiconductor substrate 21 in order to improve the film quality of the silicon oxide film 25. Thereafter, the silicon oxide film 25 is polished by the CMP (chemical mechanical polishing) method using the silicon nitride film as a stopper so as to leave the silicon oxide film 25 in the trench, whereby the element isolation trench 26 having a planarized surface is formed.

Subsequently, after the silicon nitride film left on the active region of the semiconductor substrate 21 is removed by the wet etching using thermal phosphoric acid, boron (B) is ion-implanted into a region of the semiconductor substrate 21 where an n channel MISFET is formed, and thereby forming a p well 27.

Subsequently, after the silicon oxide film of the p well 27 is removed using a washing liquid containing HF (hydrofluoric acid), the wet oxidation of the semiconductor substrate 21 is carried out to form a clean gate oxide film 29 having a film thickness of about 3.5 nm on the surface of the p well 27.

Next, a non-doped polycrystalline silicon film having a film thickness of 90 to 100 nm is deposited on the resultant structure on the semiconductor substrate 21 by the CVD method. Subsequently, phosphorus (P) is ion-implanted into the non-doped polycrystalline silicon film on the p well 27 using an ion-implantation mask, thereby forming an n polycrystalline silicon film. Furthermore, a silicon oxide film is deposited on a surface of the n polyrcrystalline silicon film to form a laminated film, and then, the laminated film is etched with using the patterned photoresist film as a mask by the photolithography to form a gate electrode 30 and a cap insulating film 31A. Note that a refractory metal silicide film such as WSiₓ, MoSiₓ, TiSiₓ, TaSiₓ, and CoSiₓ may be laminated on the gate electrode 30. The cap insulating film 31A can be formed by, for example, the CVD method.

Next, after removing the photoresist film used in the process of the gate electrode 30, an n impurity, for example, phosphorus (P) is ion-implanted into the p well 27 to form n⁻ semiconductor regions 32 on both sides of the gate electrode 30 in the p well 27.

Next, a silicon oxide film having a film thickness of about 100 nm is deposited on the resultant structure on the semiconductor substrate 21 by the CVD method, and anisotropic etching is performed to the silicon oxide film using the reactive ion etching (RIE) method, thereby forming a sidewall spacer 31B on the sidewall of the gate electrode 30 of the n channel MISFET. Subsequently, an n impurity, for example, arsenic (As) is ion-implanted into the p well 27 to form n⁺ semiconductor regions 33 (source and drain) of the n channel MISFET. As a result, the source region and the drain region having the LDD (lightly Doped Drain) structure are formed in the n channel MISFET Qn, and the n channel MISFET Qn is completed.

Next, after depositing a silicon oxide film on the resultant structure on the semiconductor substrate 21 by the CVD method, the silicon oxide film is polished by the CMP method to form an insulating film 34 having a planarized surface. Subsequently, as shown in FIG. 15, connection holes 35 are formed through the insulating film 34 on the n⁺ semiconductor region 33 on the main surface of the semiconductor substrate 21 by the photolithography technique.

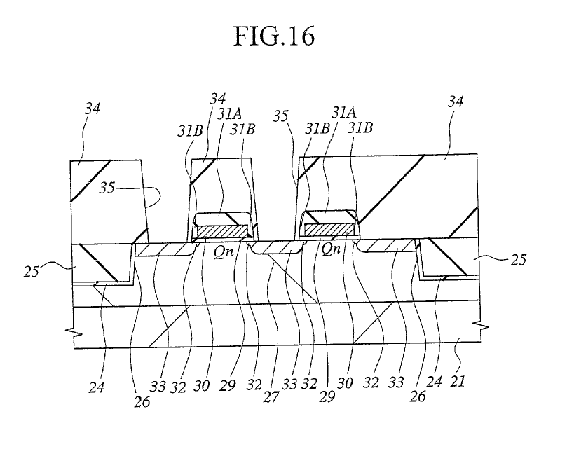

Next, as shown in FIG. 16, the surface treatment of the semiconductor substrate 21 is performed by the sputter etching so as to remove the reactive layer on the surface of the n⁺ semiconductor region 33 exposed on the bottom portion of the connection hole 35. At this time, the connection hole 35 is processed so as to have a tapered shape, that is, the bottom portion of the connection hole 35 is narrower in comparison to the upper portion thereof. Note that this sputter etching step is performed by using the semiconductor manufacturing apparatus according to the first embodiment, and the semiconductor substrate 21 (wafer 9) to which the steps until the connection hole 35 is formed have been performed is stored in the load-lock chamber 2 (refer to FIG. 1).

The entire image of the semiconductor substrate 21 taken out from the load-lock chamber 2 is first photographed by the camera 8 (refer to FIG. 3) before performing the sputter etching step. Thereafter, the presence of the breakage or the crack of the semiconductor substrate 21 is determined according to the steps described above by the use of FIG. 4, and if there is no breakage or crack detected, the semiconductor substrate 21 is transported to the process chamber 3A. The process chamber 3A is used as a sputter etching apparatus in this case, and the inside of the process chamber 3A is filled with, for example, argon (Ar) and the sputter etching is performed to the resultant structure on the semiconductor substrate 21 under this Ar atmosphere.

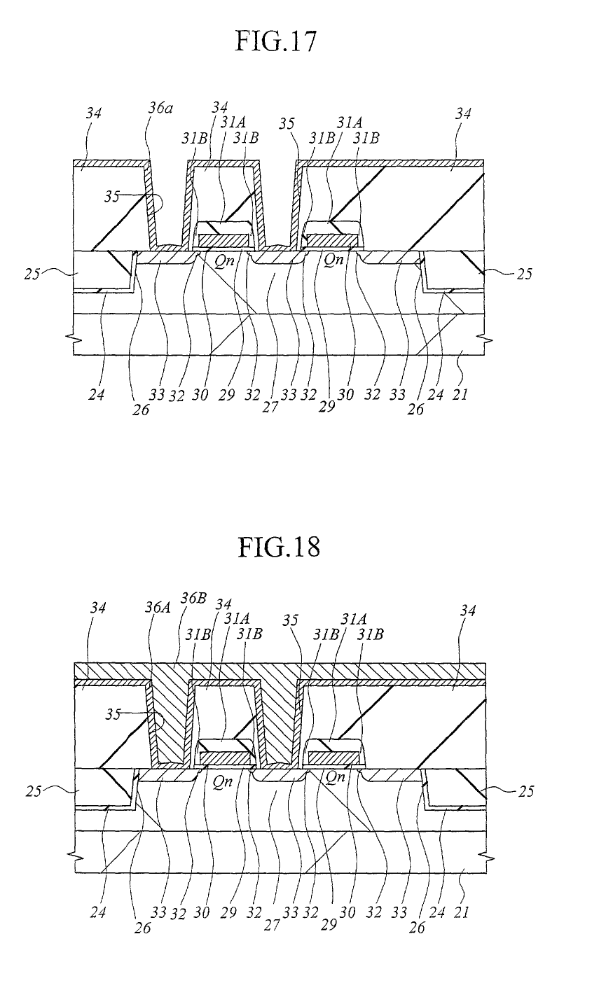

Next, the semiconductor substrate 21 to which the sputter etching step has been performed is taken out from the process chamber 3A, and the presence of the breakage or the crack of the semiconductor substrate 21 is determined according to the steps described above by the use of FIG. 4. If there is no breakage or crack detected, the semiconductor substrate 21 is transported to the process chamber 3B. The process chamber 3B is used as a sputtering apparatus in this case, and in the process chamber 3B, a barrier conductor film 36A made of, for example, titanium nitride (TiN) is deposited (FIG. 17) on the resultant structure on the semiconductor substrate 21 (including the inside of the connection hole 35) to which the step of the sputter etching has been performed.

The breakage and the crack sometimes occur on the semiconductor substrate 21 due to the thermal stress applied during the manufacturing process of the semiconductor integrated circuit device and the transportation trouble. Particularly, such breakage and crack frequently occur in the case where the manufacturing process thereof uses heat, that is, in the case where the manufacturing process employs the sputtering method (physical deposition method) used in the deposition of the barrier conductor film 36A, the CVD method, the dry etching method, or the like.

In this sense, the semiconductor substrate 21 having the barrier conductor film 36A formed thereon is taken out from the process chamber 3B, the presence of the breakage or the crack on the semiconductor substrate 21 is determined according to the steps described above by the use of FIG. 4, and if there is no breakage or crack detected, the semiconductor substrate 21 is transported to the process chamber 3C. The process chamber 3C is used as a CVD apparatus in this case, and in the process chamber 3C, a conductive film 36B made of, for example, tungsten is formed on the semiconductor substrate 21 having the barrier conductor film 36A formed thereon (FIG. 18). The semiconductor substrate 21 having the conductive film 36B formed thereon is stored again in the load-lock chamber 2.

In the description made by the use of FIG. 1, the case where the semiconductor manufacturing apparatus according to the first embodiment had four process chambers 3A to 3D was exemplified. In the above-described manufacturing process of the semiconductor integrated circuit device, however, the semiconductor manufacturing apparatus is used only in three steps, that is, the sputter etching step, the step of depositing the barrier conductor film 36A, and the step of depositing the conductive film 36B. Therefore, three process chambers are sufficient to be provided in the semiconductor manufacturing apparatus according to the first embodiment.

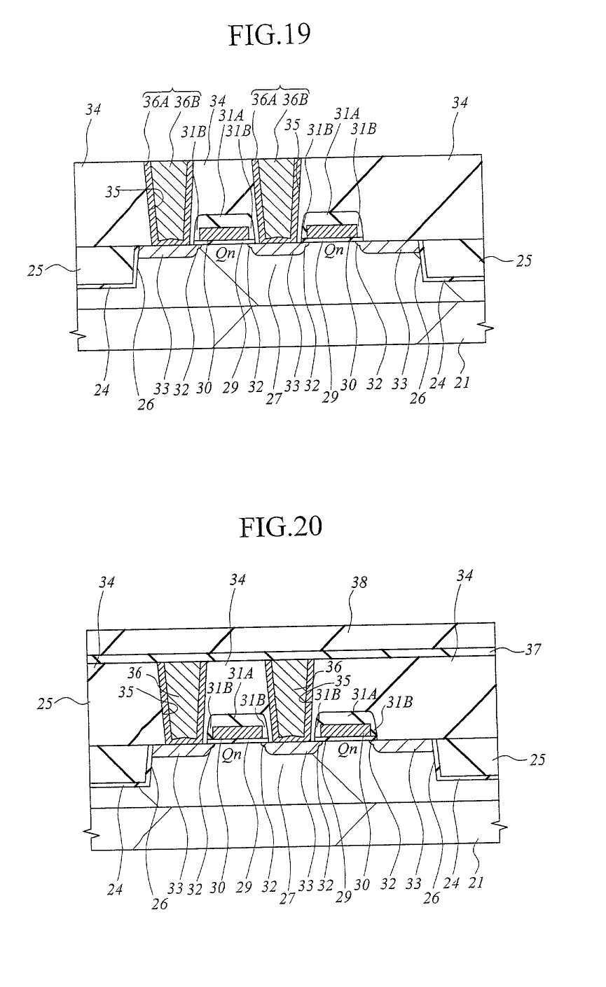

Next, as shown in FIG. 19, the barrier conductor film 36A and the conductive film 36B on the insulating film 34 other than those formed in the connection hole 35 are removed by, for example, the CMP method, and thus, a plug 36 is formed.

Next, as shown in FIG. 20, a silicon nitride film is deposited on the resultant structure on the semiconductor substrate 21 by, for example, the plasma CVD method, thereby forming an etching stopper film 37 having a film thickness of about 100 nm. The etching stopper film 37 has a function to prevent the damage to the lower layer and the deterioration of the dimensional accuracy due to the over etching in the process when a trench or a hole for forming a wiring is formed on the insulating film in the upper layer of the etching stopper film 37.

Subsequently, a silicon oxide film is deposited on a surface of the etching stopper film 37 by the CVD method, thereby forming an insulating film 38 having a film thickness of about 400 nm. This insulating film 38 can be made of a SOG (Spin On Glass) film deposited by the coating method, a low dielectric constant film such as the CVD oxide film added with fluorine, a silicon nitride film, or the one made by combining various kinds of insulating films. When the low dielectric constant film is used, the overall dielectric constant of the wiring of the semiconductor integrated circuit device can be reduced, which makes it possible to improve the wiring delay.

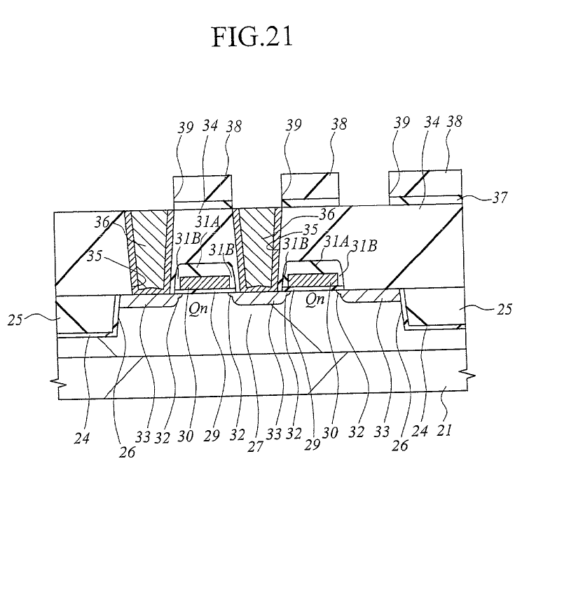

Next, as shown in FIG. 21, the etching stopper film 37 and the insulating film 38 are processed by using the photolithography technique and the dry etching technique to form a wiring trench 39.

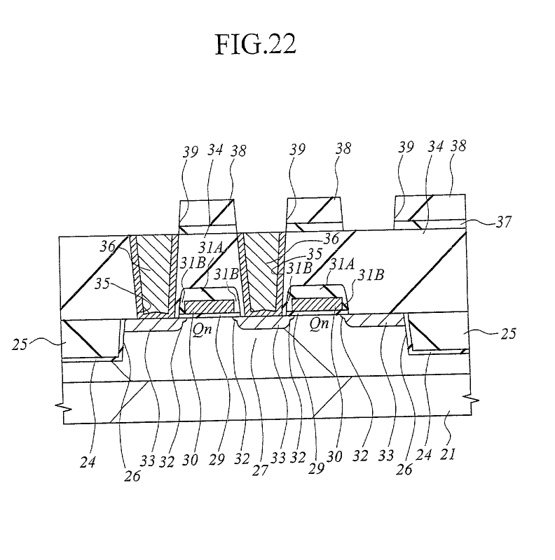

Next, as shown in FIG. 22, a surface treatment of the semiconductor substrate 21 is performed by the sputter etching in the argon (Ar) atmosphere so as to remove the reactive layer on the surface of the plug 36 exposed on the bottom portion of the wiring trench 39. At this time, the wiring trench 39 is processed so as to have a tapered shape, that is, the bottom portion of the wiring trench 39 is narrower in comparison to the upper portion thereof. Note that this sputter etching step is performed by using the semiconductor manufacturing apparatus according to the first embodiment, and the load-lock chamber 2 stores therein the semiconductor substrate 21 to which the steps until forming the wiring trench 39 have been performed.

The entire image of the semiconductor substrate 21 taken out from the load-lock chamber 2 is first photographed by the camera 8 (refer to FIG. 3) when performing the sputter etching step. Thereafter, the presence of the breakage or the crack of the semiconductor substrate 21 is determined according to the steps described above by the use of FIG. 4, and if there is no breakage or crack detected, the semiconductor substrate 21 is transported to the process chamber 3A. The process chamber 3A is used as a sputter etching apparatus in this case, and the inside of the process chamber is filled with, for example, Ar and the sputter etching is performed to the resultant structure on the semiconductor substrate 21 under this Ar atmosphere.

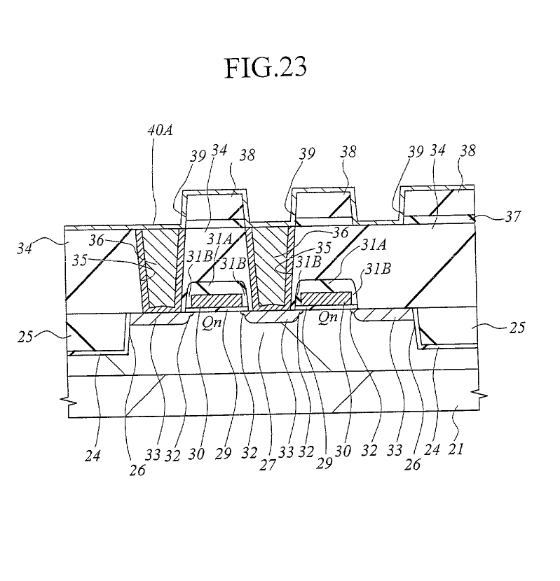

Next, the semiconductor substrate 21 to which the sputter etching step has been performed is taken out from the process chamber 3A, and the presence of the breakage or the crack of the semiconductor substrate 21 is determined according to the steps described above by the use of FIG. 4. If there is no breakage or crack detected, the semiconductor substrate 21 is transported to the process chamber 3B. The process chamber 3B is used as a sputtering apparatus in this case, and in the process chamber 3B, a barrier conductor film 40A made of, for example, TiN is deposited (FIG. 23) on the resultant structure on the semiconductor substrate 21 (including the inside of the wiring trench 39) to which the step of the sputter etching has been performed.

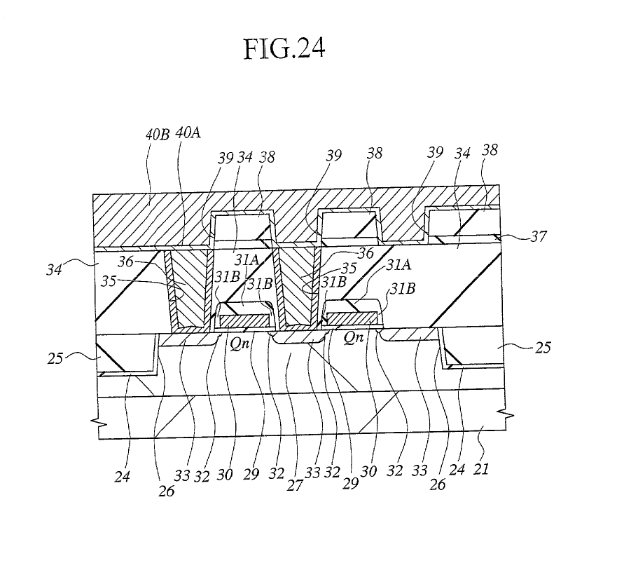

Next, the semiconductor substrate 21 on which the barrier conductor film 40A is formed is taken out from the process chamber 3B, and the presence of the breakage or the crack of the semiconductor substrate 21 is determined according to the steps described above by the use of FIG. 4. If there is no breakage or crack detected, the semiconductor substrate 21 is transported to the process chamber 3C. The process chamber 3C is used as a sputtering apparatus in this case, and in the process chamber 3C, a conductive film 40B made of copper (Cu) or copper alloy is deposited (FIG. 24) on the resultant structure on the semiconductor substrate 21 on which the barrier conductor film 40A is formed. The semiconductor substrate 21 on which the conductive film 40B is formed is stored again in the load-lock chamber 2. In this case, the process chamber 3D (refer to FIG. 1) is not required similarly to the process including the sputter etching step, the step of depositing the barrier conductor film 36A, and the step of depositing the conductive film 36B described by the use of FIGS. 16 to 18. Therefore, it is sufficient to provide three process chambers in the semiconductor manufacturing apparatus according to the first embodiment.

In the first embodiment, the TiN film is exemplified as the barrier conductor film 40A. However, a metal film made of tantalum (Ta), a laminated film made of metal films, and a laminated film made of metal films and nitride films, or the like can be used as the barrier conductor film 40A. In the case where the Ta film or the tantalum nitride (TaN) film is used as the barrier conductor film, better adhesion to the conductive film 40B as a Cu film can be achieved in comparison to the case where the TiN film is used.

Also, when a TiN film is used as the barrier conductor film 40A, the sputter etching of a surface of the TiN film can be performed immediately before forming the conductive film 40B. The semiconductor manufacturing apparatus according to the first embodiment can cope with such a case by additionally providing a process chamber. By the sputter etching as described above, moisture, oxygen molecules, and the like adsorbing to the surface of the TiN film are removed, and thus, the adhesion of the conductive film 40B can be improved. This technique is quite effective especially in the case where the surface of the TiN film is exposed to the air by the vacuum break after depositing the TiN film to form the conductive film 40B. Note that the technique is effectively applied not only to the TiN film but also to the TaN film though there is some difference in its effect.

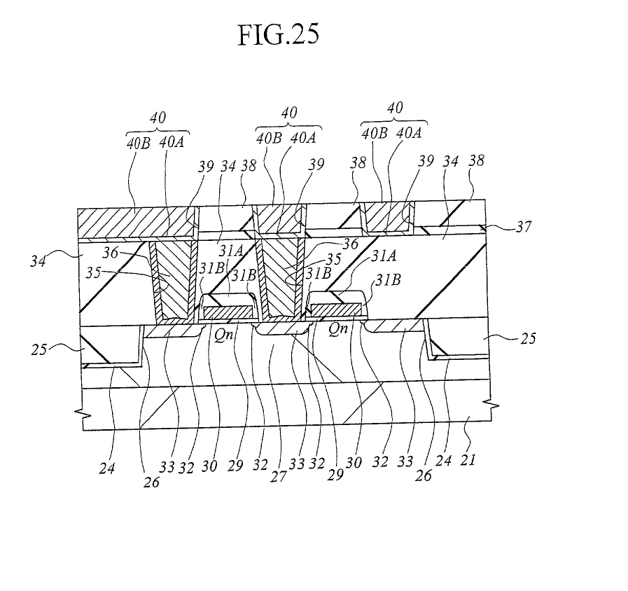

Next, as shown in FIG. 25, a wiring 40 is formed by removing the superfluous barrier conductor film 40A and the conductive film 40B on the insulating film 38 to leave the barrier conductor film 40A and the conductive film 40B in the wiring trench 39, whereby the semiconductor integrated circuit device according to the first embodiment is manufactured. The removal of the barrier conductor film 40A and the conductive film 40B is performed by the polishing using, for example, the CMP method.

(Second Embodiment)

The method of manufacturing a semiconductor integrated circuit device according to the second embodiment is another example of the method of manufacturing a semiconductor integrated circuit device using the semiconductor manufacturing apparatus according to the first embodiment.

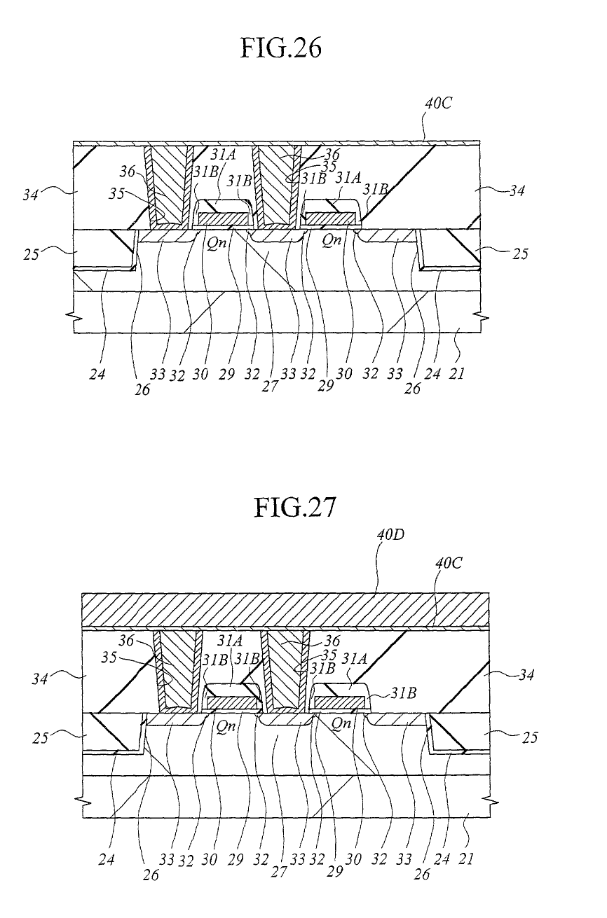

The method of manufacturing a semiconductor integrated circuit device according to the second embodiment will be described by the use of FIGS. 26 to 31.

The method of manufacturing a semiconductor integrated circuit device according to the second embodiment is identical to that in the first embodiment until the process proceeds to the step described by the use of FIGS. 14 to 19.

Thereafter, as shown in FIG. 26, a conductive film 40C made of, for example, TiN is deposited on the entire surface of a semiconductor substrate 1 by the sputtering method. Note that the deposition step of the conductive film 40C is carried out by using the semiconductor manufacturing apparatus according to the first embodiment, and the load-lock chamber 2 (refer to FIG. 1) stores therein the semiconductor substrate 21 (wafer 9) to which the steps until forming the plug 36 have been performed.

Before the step of depositing the conductive film 40C, the entire image of the semiconductor substrate 21 taken out from the load-lock chamber 2 is photographed by the camera 8 (refer to FIG. 3). Thereafter, the presence of the breakage or the crack of the semiconductor substrate 21 is determined according to the steps described above by the use of FIG. 4 in the first embodiment. If there is no breakage or crack detected, the semiconductor substrate 21 is transported to the process chamber 3A. Note that the process chamber 3A is used as a sputtering apparatus in this case, and the conductive film 40C is deposited on the resultant structure on the semiconductor substrate 21 in the process chamber 3A.

Next, the semiconductor substrate 21 having the conductive film 40C formed thereon is taken out from the process chamber 3A, and the presence of the breakage or the crack of the semiconductor substrate 21 is determined according to the steps described above by the use of FIG. 4 in the first embodiment. If there is no breakage or crack detected, the semiconductor substrate 21 is transported to the process chamber 3B. The process chamber 3B is used as a sputtering apparatus in this case, and, in the process chamber 3B, a conductive film 40D made of, for example, aluminum (Al) is deposited on the resultant structure on the semiconductor substrate 21 having the conductive film 40C formed thereon (FIG. 27).

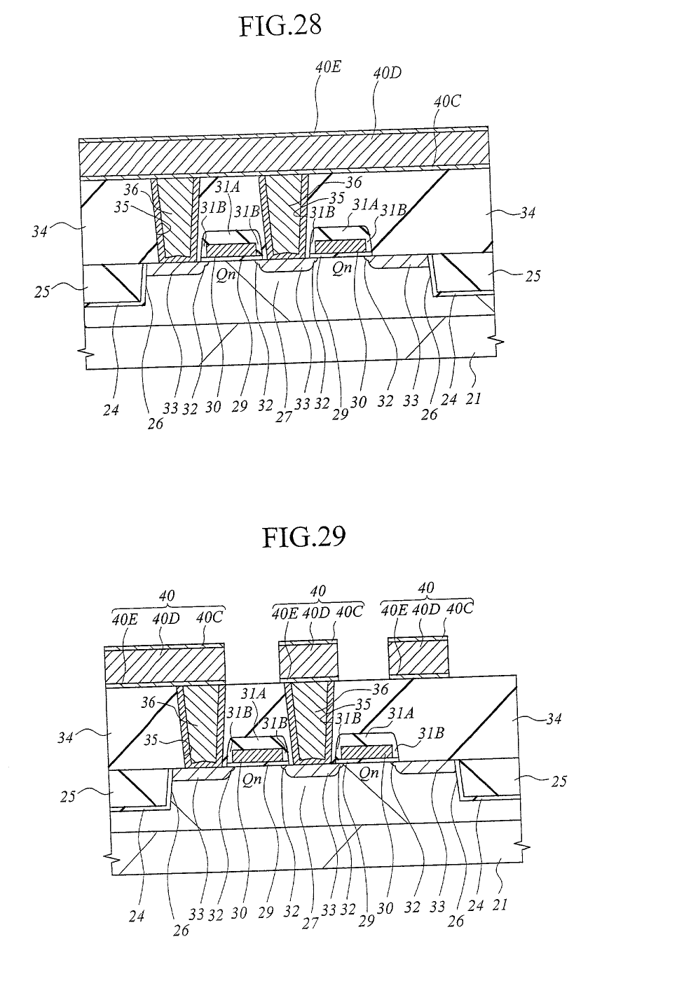

Next, the semiconductor substrate 21 having the conductive film 40D formed thereon is taken out from the process chamber 3B, and the presence of the breakage or the crack of the semiconductor substrate 21 is determined according to the steps described above by the use of FIG. 4 in the first embodiment. If there is no breakage or crack detected, the semiconductor substrate 21 is transported to the process chamber 3C. The process chamber 3C is used as a sputtering apparatus in this case, and a conductive film 40E made of, for example, TiN is deposited on the resultant structure on the semiconductor substrate 21 having the conductive film 40D formed thereon (FIG. 28). The semiconductor substrate 21. having the conductive film 40E formed thereon is stored again in the load-lock chamber 2.

In the description made by the use of FIG. 1 in the first embodiment, the case where the semiconductor manufacturing apparatus according to the first embodiment had four process chambers 3A to 3D was exemplified. In the above-described manufacturing process of the semiconductor integrated circuit device according to the second embodiment, however, the semiconductor manufacturing apparatus is used only in three steps, that is, the steps of depositing the conductive films 40C to 40E. Therefore, three process chambers are sufficient to be provided in the semiconductor manufacturing apparatus according to the second embodiment.

Next, as shown in FIG. 29, the conductive films 40C to 40E are processed by the dry etching technique so as to form the wiring 40.

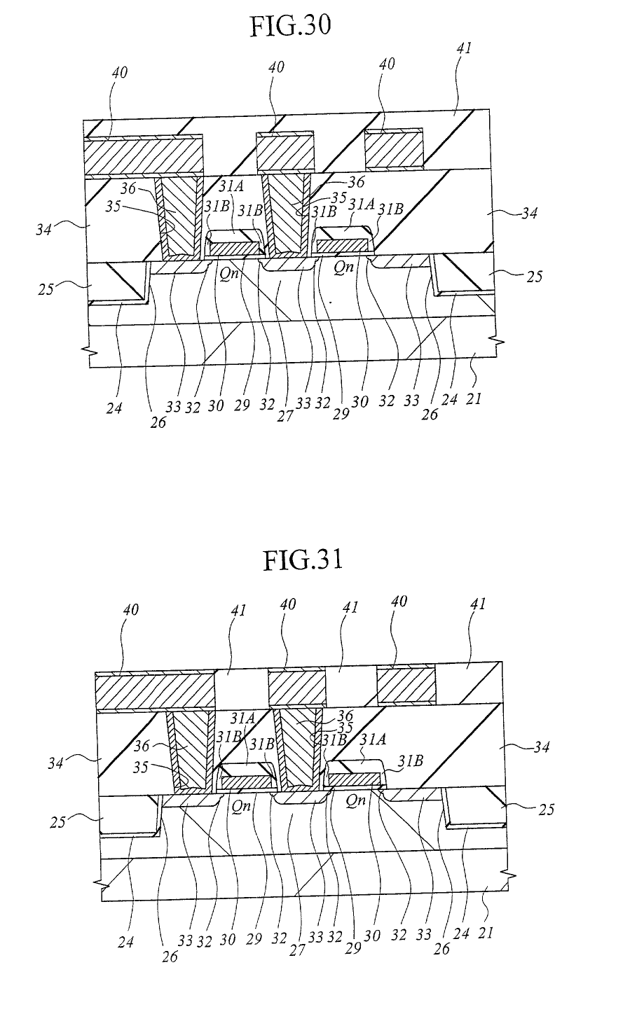

Next, as shown in FIG. 30, a silicon oxide film is deposited on the resultant structure on the semiconductor substrate 21 by the CVD method, thereby forming an insulating film 41. Subsequently, as shown in FIG. 31, the insulating film 41 is polished by the CMP method with using the conductive film 40 as a polish endpoint, and thus, the semiconductor integrated circuit device according to the second embodiment is manufactured.

In the foregoing, the invention made by the inventors thereof was concretely described based on the embodiments. However, it goes without saying that the present invention is not limited to the foregoing embodiments and the various changes and modifications can be made within the scope of the present invention.

For example, in the foregoing embodiment, the case where the CVD method is used to deposit the W film when forming the plug was described. However, the sputtering method can also be used thereto.

The advantages achieved by the typical ones of the inventions disclosed in this application will be briefly described as follows.

That is, wafer inspection is carried out by photographing the entire image of a wafer, and then processing the photographed image, whereby it is possible to detect the damage on a part of the wafer such as a breakage and a crack without fail.

What is claimed is:

1. A method of manufacturing a semiconductor integrated circuit device performed in a semiconductor manufacturing apparatus having a plurality of chambers, comprising the steps of:
(a) obtaining a flat entire image of a semiconductor wafer after performing a first process to said semiconductor wafer in a first chamber of said plurality of chambers and before performing a second process to said semiconductor wafer in a second chamber of said plurality of chambers;
(b) determining the condition of said semiconductor wafer by examining said flat entire image of the semiconductor wafer;
(c) transporting said semiconductor wafer to said second chamber and performing said second process to said semiconductor wafer when said semiconductor wafer is determined to be in proper condition in said step (b); and
(d) stopping the operation of said semiconductor manufacturing apparatus when said semiconductor wafer is determined to be in improper condition in said step (b).

2. The method of manufacturing a semiconductor integrated circuit device according to claim 1, wherein, in said step (b), the condition of said semiconductor wafer is determined by comparing a flat entire image of a good semiconductor wafer recorded in advance and said flat entire image of said semiconductor wafer obtained in said step (a).

3. The method of manufacturing a semiconductor integrated circuit device according to claim 1, wherein said first process includes a heat treatment method, a physical deposition method, a chemical deposition method, and a dry etching.

4. A method of manufacturing a semiconductor integrated circuit device using a semiconductor manufacturing apparatus having a plurality of chambers, comprising the steps of:
(a) transporting a semiconductor wafer to a first chamber of said plurality of chambers, and then performing a first process to said semiconductor wafer;
(b) photographing a flat entire image of said semiconductor wafer by a photographing unit after taking out said semiconductor wafer from said first chamber, and setting the photographed flat entire image as a first image;
(c) taking said first image in a discrimination unit and comparing a flat entire image of a good semiconductor wafer recorded in advance with said first image, thereby determining the presence of the damages on said semiconductor wafer;
(d) stopping the operation of said semiconductor manufacturing apparatus when it is determined that said semiconductor wafer is damaged in said step (c); and
(e) transporting said semiconductor wafer to said second chamber and performing a second process to said semiconductor wafer when it is determined that said semiconductor wafer is not damaged in said step (c).

5. The method of manufacturing a semiconductor integrated circuit device according to claim 4, wherein said first image is displayed by a series of gradual stages of color.

6. The method of manufacturing a semiconductor integrated circuit device according to claim 4, wherein said first process includes a heat treatment method, a physical deposition method, a chemical deposition method, and a dry etching.

7. A method of manufacturing a semiconductor integrated circuit device using a semiconductor manufacturing apparatus having a plurality of chambers, comprising the steps of:
(a) transporting a semiconductor wafer to a first chamber of said plurality of chambers, and performing a heat treatment to a first surface of said semiconductor wafer or forming a first thin film on the first surface of said semiconductor wafer;
(b) photographing a flat entire image of said semiconductor wafer by a photographing unit after taking out said semiconductor wafer from said first chamber, and setting the photographed flat entire image as a first image;
(c) taking said first image in a discrimination unit and comparing a flat entire image of a good semiconductor wafer recorded in advance with said first image, thereby determining whether the position of said heat treatment applied to or that of said first thin film formed on said first surface is proper or improper; and
(d) stopping the operation of said semiconductor manufacturing apparatus when it is determined in said step (c) that said position of said heat treatment applied to or that of said first thin film formed on said first surface of said semiconductor wafer is displaced from a predetermined position.

8. A method of manufacturing a semiconductor integrated circuit device using a semiconductor manufacturing apparatus having a plurality of chambers, comprising the steps of:
(a) transporting a semiconductor wafer to a first chamber of said plurality of chambers, and performing a heat treatment to a first surface of said semiconductor wafer or forming a first thin film on the first surface of said semiconductor wafer;
(b) photographing a flat entire image of said semiconductor wafer by a photographing unit after taking out said semiconductor wafer from said first chamber, and setting the photographed flat entire image as a first image;
(c) taking said first image in a discrimination unit and comparing a flat entire image of a good semiconductor wafer recorded in advance with said first image, thereby determining whether or not said heat treatment is performed to said first surface of said semiconductor wafer or whether or not said first thin film is formed on said first surface of said semiconductor wafer; and
(d) stopping the operation of said semiconductor manufacturing apparatus when it is determined in said step (c) that said heat treatment is not performed to said first surface of said semiconductor wafer or that said first thin film is not formed on said first surface of said semiconductor wafer.

9. A method of manufacturing a semiconductor integrated circuit device performed in a semiconductor manufacturing apparatus in which a plurality of chambers are mechanically connected to load-lock chambers capable of storing a plurality of wafers via a transport chamber, comprising the steps of:
(a) transporting a semiconductor wafer to a first chamber of said plurality of chambers through said transport chamber after taking out said semiconductor wafer from said load-lock chamber, photographing a flat entire image of said semiconductor wafer by a photographing unit before performing a first process to said semiconductor wafer, and then, setting the photographed flat entire image as a first image;
(b) taking said first image in a discrimination unit and comparing a flat entire image of a good semiconductor wafer recorded in advance with said first image, thereby determining the presence of damages on said semiconductor wafer;
(c) stopping the operation of said semiconductor manufacturing apparatus when it is determined in said step (b) that said semiconductor wafer is damaged;
(d) transporting said semiconductor wafer to said first chamber and performing said first process to said semiconductor wafer when it is determined in said step (b) that said semiconductor wafer is not damaged.

10. A method of manufacturing a semiconductor integrated circuit device performed in a semiconductor manufacturing apparatus in which a plurality of chambers are mechanically connected to load-lock chambers capable of storing a plurality of wafers via a transport chamber, comprising the steps of:
(a) photographing a flat entire image of said semiconductor wafer by a photographing unit after performing a first process to said semiconductor wafer in a first chamber of said plurality of chambers and before transporting said semiconductor wafer to said load-lock chamber, and setting the photographed flat entire image as a first image;
(b) taking said first image in a discrimination unit and determining the presence of the damages on said semiconductor wafer by comparing a flat entire image of a good semiconductor wafer recorded in advance with said first image;
(c) stopping the operation of said semiconductor manufacturing apparatus when it is determined in said step (b) that said semiconductor wafer is damaged; and
(d) transporting said semiconductor wafer to said load-lock chamber when it is determined in said step (b) that said semiconductor wafer is not damaged.

11. A method of manufacturing a semiconductor integrated circuit device using a semiconductor manufacturing apparatus having a plurality of chambers, comprising the steps of:
(a) transporting said plurality of wafers to a predetermined number of first chambers of said plurality of chambers one by one and performing a first process to said semiconductor wafer;
(b) photographing a flat entire image of said semiconductor wafer by a photographing unit after taking out said semiconductor wafer from said first chamber, and setting the photographed flat entire image as a first image;
(c) taking said first image in a discrimination unit and determining the presence of the damages on said semiconductor wafer by comparing a flat entire image of a good semiconductor wafer recorded in advance with said first image; and
(d) stopping the operation of said semiconductor manufacturing apparatus when it is determined in said step (c) that said semiconductor wafer is damaged.

12. A method of manufacturing a semiconductor integrated circuit device using a semiconductor manufacturing apparatus having a plurality of chambers, comprising the steps of:
(a) transporting said plurality of wafers to a predetermined number of first chambers of said plurality of chambers one by one, and performing a heat treatment to a first surface of said semiconductor wafer or forming a first thin film on the first surface of said semiconductor wafer;
(b) photographing a flat entire image of said semiconductor wafer by a photographing unit after taking out said semiconductor wafer from said first chamber, and setting the photographed flat entire image as a first image;
(c) taking said first image in a discrimination unit and determining whether the position of said heat treatment applied to or that of said first thin film formed on said first surface is proper or improper by comparing a flat entire image of a good semiconductor wafer recorded in advance with said first image; and
(d) stopping the operation of said semiconductor manufacturing apparatus when it is determined in said step (c) that said position of said heat treatment applied to or that of said first thin film formed on said first surface of said semiconductor wafer is displaced from a predetermined position.

13. A method of manufacturing a semiconductor integrated circuit device using a semiconductor manufacturing apparatus having a plurality of chambers, comprising the steps of:
(a) transporting a plurality of semiconductor wafers to a predetermined number of first chambers of said plurality of chambers one by one, and performing a heat treatment to a first surface of said semiconductor wafer or forming a first thin film on the first surface of said semiconductor wafer;
(b) photographing a flat entire image of said semiconductor wafer after taking out said semiconductor wafer from said first chamber, and setting the photographed flat entire image as a first image;
(c) taking said first image in a discrimination unit and determining whether or not said heat treatment is performed to said first surface of said semiconductor wafer or whether or not said first thin film is formed on said first surface of said semiconductor wafer by comparing a flat entire image of a good semiconductor wafer recorded in advance with said first image; and
(d) stopping the operation of said semiconductor manufacturing apparatus when it is determined in said step (c) that said heat treatment is not performed to said first surface of said semiconductor wafer or that said first thin film is not formed on said first surface of said semiconductor wafer.

14. A semiconductor manufacturing apparatus,
wherein a plurality of chambers and a transport chamber are mechanically connected to each other; a photographing unit for obtaining a flat entire image of a semiconductor wafer, to which a predetermined process has been performed in a predetermined chamber of said plurality of chambers, is provided in said transport chamber; said semiconductor manufacturing apparatus has a function to determine the condition of said semiconductor wafer in proper or improper by examining said flat entire image of said semiconductor wafer; and said semiconductor manufacturing apparatus has a function to stop the operation of itself when it is determined that said semiconductor wafer is in improper condition.

15. The semiconductor manufacturing apparatus according to claim 14,
wherein said function to determine whether said semiconductor wafer is in proper condition or in improper condition is a function to determine whether said semiconductor wafer is in proper condition or in improper condition by comparing a flat entire image of a good semiconductor wafer recorded in advance with the flat entire image of the semiconductor wafer to which a predetermined process has been performed in said first chamber.

16. A semiconductor manufacturing apparatus,
wherein a plurality of chambers and a transport chamber are mechanically connected to each other; a photographing unit for obtaining a flat entire image of a semiconductor wafer, to which a predetermined process has been performed in a predetermined chamber of said plurality of chambers, is provided in said transport chamber; said semiconductor manufacturing apparatus has a discrimination unit to determine whether said semiconductor wafer is damaged or not by taking the flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit determines that said semiconductor wafer is damaged.

17. The semiconductor manufacturing apparatus according to claim 16,
wherein said discrimination unit has a function to display said flat entire image of said semiconductor wafer by a series of gradual stages of color when comparing said flat entire image of said semiconductor wafer with said flat entire image of said good semiconductor wafer.

18. A semiconductor manufacturing apparatus,
wherein a plurality of chambers and a transport chamber are mechanically connected to each other; said transport chamber has a photographing unit for obtaining a flat entire image of a semiconductor wafer having a first surface on which a heat treatment is applied or a first thin film is formed in a predetermined chamber of said plurality of chambers; said semiconductor manufacturing apparatus has a discrimination unit functioning to determine whether a position of said heat treatment or that of said first thin film on said first surface is proper or improper by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit determines that said position of said heat treatment or that of said first thin film on said first surface is displaced from a predetermined position.

19. A semiconductor manufacturing apparatus,
wherein a plurality of chambers and a transport chamber are mechanically connected to each other; said transport chamber has a photographing unit for obtaining a flat entire image of a semiconductor wafer having a first surface on which a heat treatment is applied or a first thin film is formed in a predetermined chamber of said plurality of chambers; said semiconductor manufacturing apparatus has a discrimination unit functioning to determine whether or not said heat treatment is applied or whether or not said first thin film is formed on said first surface of said semiconductor wafer by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit detects that said heat treatment is not applied or that said first thin film is not formed on said first surface of said semiconductor wafer.

20. A semiconductor manufacturing apparatus,
wherein a plurality of chambers are mechanically connected to load-lock chambers capable of storing a plurality of wafers via a transport chamber; one of said semiconductor wafers is taken out from said load-lock chamber, and then the semiconductor wafer is transported to a first chamber of said plurality of chambers through said transport chamber; a photographing unit for obtaining a flat entire image of said semiconductor wafer before performing a first process to said semiconductor wafer is provided; said semiconductor manufacturing apparatus has a discrimination unit functioning to determine the presence of damages on said semiconductor wafer by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit determines that said semiconductor wafer is damaged.

21. A semiconductor manufacturing apparatus,
wherein a plurality of chambers are mechanically connected to load-lock chambers capable of storing a plurality of wafers via a transport chamber; a photographing unit for obtaining a flat entire image of said semiconductor wafer after performing a first process to a semiconductor wafer in a first chamber of said plurality of chambers and before transporting said semiconductor wafer to said load-lock chamber is provided; said semiconductor manufacturing apparatus has a discrimination unit functioning to determine the presence of damages on said semiconductor wafer by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit determines that said semiconductor wafer is damaged.

22. A semiconductor manufacturing apparatus,
wherein a plurality of chambers and a transport chamber are mechanically connected. to each other; a predetermined number of first chambers of said plurality of chambers have a function to perform a first process to said semiconductor wafer after said semiconductor wafer is transported one by one; a photographing unit for obtaining the flat entire image of said semiconductor wafer to which said first process has been performed in said first chamber is provided in said transport chamber; said semiconductor manufacturing apparatus has a discrimination unit functioning to determine the presence of damages on said semiconductor wafer by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit determines that said semiconductor wafer is damaged.

23. A semiconductor manufacturing apparatus,
wherein a plurality of chambers and a transport chamber are mechanically connected to each other; a predetermined number of first chambers of said plurality of chambers have a function to apply a heat treatment to a first surface of a semiconductor wafer or to form a first thin film on the first surface of said semiconductor wafer after transporting said semiconductor wafer one by one; a photographing unit for obtaining the flat entire image of said semiconductor wafer having said first surface to which said heat treatment has been applied or on which said first thin film is formed in said first chamber is provided in said transport chamber; said semiconductor manufacturing apparatus has a discrimination unit functioning to determine whether a position of said heat treatment or that of said first thin film on said first surface is proper or improper by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit determines that said position of said heat treatment or that of said first thin film on said first surface is displaced from a predetermined position.

24. A semiconductor manufacturing apparatus,
wherein a plurality of chambers and a transport chamber are mechanically connected to each other; a predetermined number of first chambers of said plurality of chambers have a function to apply a heat treatment to a first surface of a semiconductor wafer or to form a first thin film on the first surface of said semiconductor wafer after transporting said semiconductor wafer one by one; a photographing unit for obtaining the flat entire image of said semiconductor wafer having said first surface to which said heat treatment has been applied or on which said first thin film has been formed in said first chamber is provided in said transport chamber; said semiconductor manufacturing apparatus has a discrimination unit functioning to determine whether or not said heat treatment is applied or whether or not said first thin film is formed on said first surface of said semiconductor wafer by taking said flat entire image of said semiconductor wafer and comparing a flat entire image of a good semiconductor wafer recorded in advance with said flat entire image of said semiconductor wafer; and said semiconductor manufacturing apparatus has a function to stop the operation of itself when said discrimination unit detects that said heat treatment is not performed or that said first thin film is not formed on said first surface of said semiconductor wafer.
